(19) United States
(12) Patent Application Publication
(10) Pub. No.: US 2010/0219908 A1
(43) Pub. Date: Sep. 2, 2010

(54) DIGITAL TO ANALOG CONVERTING METHOD AND DIGITAL TO ANALOG CONVERTOR UTILIZING THE SAME

(75) Inventors: Li-Chun Tu, Taipei City (TW); Chia-Wei Liao, Hsinchu County (TW); Tysh-Bin Liu, Hsinchu County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/394,068

(22) Filed: Feb. 27, 2009

(51) Int. Cl. H03H 7/00

(52) U.S. Cl. 333/172; 333/174

(57) ABSTRACT

A digital to analog converter for converting a digital input signal provided by a host to an analog output signal includes a modulator receiving the digital input signal, modulating the digital input signal, and outputting a modulated signal, and a filtering circuit receiving the modulated signal, low pass filtering the modulated signal, and outputting the analog output signal to an output node. The filtering circuit includes a first switching circuit for adjusting the bandwidth of the filtering circuit according to a bandwidth switching signal.

### BACKGROUND OF THE INVENTION

1. Field of the Invention

The invention relates to a digital to analog converters (DAC), and more particularly to a DAC with variable bandwidth.

2. Description of the Related Art

A digital to analog converter (DAC) is a circuit well-known in the art for converting a digital input signal to an analog signal. Conventional DACs receive a binary single or multi-bit digital signal on an input terminal and, as a function of a reference voltage, convert the digital signal into a corresponding analog signal. Sigma-delta DACs are one kind of popular DACs. Sigma-delta DACs utilize oversampling techniques (i.e., sampling at rates greater than the Nyquist rate) to achieve high signal-to-noise ratios (SNR). Such converters also exhibit excellent linearity. Additionally, sigma-delta converters are relatively straight-forward and inexpensive to implement due to their simplicity.

Commonly, sigma-delta DACs include a front-end interpolator which receives digital input samples and increases the sampling rate (typically 64 times the input sample rate) of the digital input samples. A sigma-delta modulator receives the higher frequency input samples from the interpolator and converts the samples to a lower accuracy (typical one-bit). Additionally, the sigma-delta modulator performs an oversampling technique referred to as “noise shaping”. “Noise shaping” is a technique by which the noise spectrum of the input samples is manipulated such that a major component of the quantization noise power is shifted to a frequency range higher than the upper frequency limit of the band of interest, which is typically the signal bandwidth. The one-bit data stream output by the modulator is converted to an analog signal by a conventional DAC and subsequent filtering is performed in the analog domain to reduce the high frequency quantization noise component of the analog output signal.

FIG. 1 shows a conventional sigma-delta DAC including an interpolation filter 11 that increases the sampling rate of a digital input signal S_{digital} by some predetermined oversampling ratio to a higher sampling rate and rejects any signal images that occur at approximately the Nyquist rate of the input signal. The higher rate digital signal is then transmitted to a sigma-delta modulator 12 that noise shapes the digital data stream and reduces the sample width to one bit. In digital to analog converters, the sigma-delta modulator is typically digital circuitry. The output of the sigma-delta modulator is typically a high frequency 1-bit data stream. The 1-bit DAC 13 receives the modulator output and provides a corresponding analog signal that is either plus or minus full scale. The output of the 1-bit DAC is transmitted to an analog smoothing filter 14 that averages the output of the 1-bit DAC, removes the shaped quantization noise that resides in the upper frequency area, and outputs analog signal S_{analog}.

Typically, the analog smoothing filter 14 is implemented as a low pass filter, and the bandwidth of the low pass filter is designed narrower for obtaining better signal-to-noise ratio (SNR) of output signal. However, the conversion time of the sigma-delta DACs is also increased as the filter bandwidth becomes narrower. Thus, a new design is needed for achieving better compromise between the conversion time and the output signal SNR.

### BRIEF SUMMARY OF THE INVENTION

Digital to analog converters for converting a digital input signal provided by a host to an analog output signal are provided. An exemplary embodiment of such a digital to analog converter comprises: a modulator receiving the digital input signal, modulating the digital input signal, and outputting a modulated signal; and a filtering circuit receiving the modulated signal, low pass filtering the modulated signal, and outputting the analog output signal to an output node, wherein the filtering circuit comprises a first switching circuit for adjusting the bandwidth of the filtering circuit according to a bandwidth switching signal.

An exemplary embodiment of a digital to analog converting method for converting a digital input signal received from a host to an analog signal comprises modulating the digital input signal to a modulated signal, and filtering the modulated signal and adjusting bandwidth by a filtering circuit, to generate an analog output signal according to a bandwidth switching signal.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a conventional sigma-delta DAC;

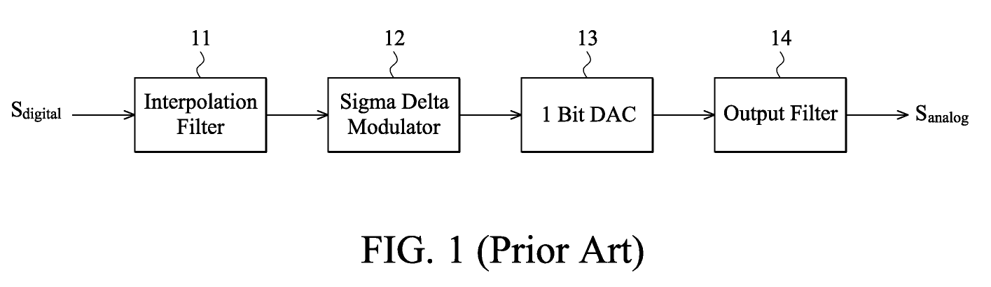

FIG. 2 shows a block diagram of a sigma-delta DAC according to an embodiment of the invention;

FIG. 3 illustrates a circuit diagram of a filtering circuit in a sigma-delta converter according to one embodiment of the invention;

FIG. 4 shows a conventional low pass filter;

FIG. 5A illustrates another circuit diagram of a filtering circuit in a sigma-delta converter according to another embodiment of the invention;

FIG. 5B illustrates another circuit diagram of a filtering circuit in a sigma-delta converter according to another embodiment of the invention;

FIG. 6 illustrates another circuit diagram of a filtering circuit in a sigma-delta converter according to another embodiment of the invention;

FIG. 7 illustrates another circuit diagram of a filtering circuit in a sigma-delta converter according to another embodiment of the invention;

FIG. 8 illustrates a block diagram of the device generating the bandwidth switching signal according to one embodiment of the invention;

FIG. 9 illustrates the signal waveforms according to the embodiment of the invention;

FIG. 10 illustrates another block diagram of the device generating the bandwidth switching signal according to one embodiment of the invention;

FIG. 11 illustrates the flow chart of a digital to analog converting method according to the embodiment of the invention;

FIG. 12 illustrates the flow chart of generating a bandwidth switching signal according to one embodiment of the invention; and

FIG. 13 illustrates the flow chart of generating a bandwidth switching signal according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

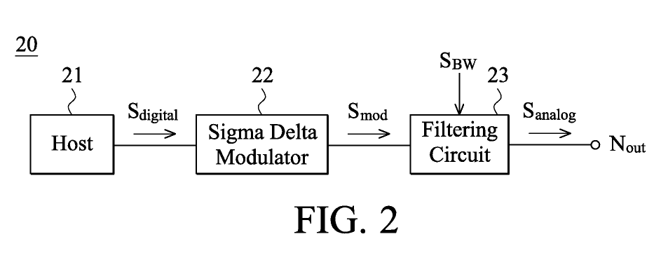

FIG. 2 shows a block diagram of a sigma-delta DAC 20 according to an embodiment of the invention. It should be noted that the embodiments described later can be applied on other kinds or different structures of digital to analog converters, and here Sigma-delta DACs is used for description convenience, should not limit the applied embodiments. As shown in FIG. 2, a sigma-delta modulator 22 receives a digital input signal S_{digital} provided by a host 21, the sigma-delta modulator 22 modulates the digital input signal S_{digital}, and outputs a modulated signal S_{mod}. A filtering circuit 23 receives the modulated signal S_{mod}, low pass filters the modulated signal S_{mod}, and outputs an analog output signal S_{analog} to an output node Nₒᵤₜ. According to one embodiment of the invention, filtering circuit 23 comprises a first switching circuit (not shown in FIG. 2, but will be illustrated in following figures) for adjusting the bandwidth of the filtering circuit 23 according to a bandwidth switching signal S_{BW}. According to the embodiments of the invention, filtering circuit 23 can be implemented as a low pass filter, or several low pass filters coupled in serial for increasing the order of the filtering circuit 23 and achieving narrower bandwidth in the frequency response and better SNR performance of the analog output signal S_{analog}.

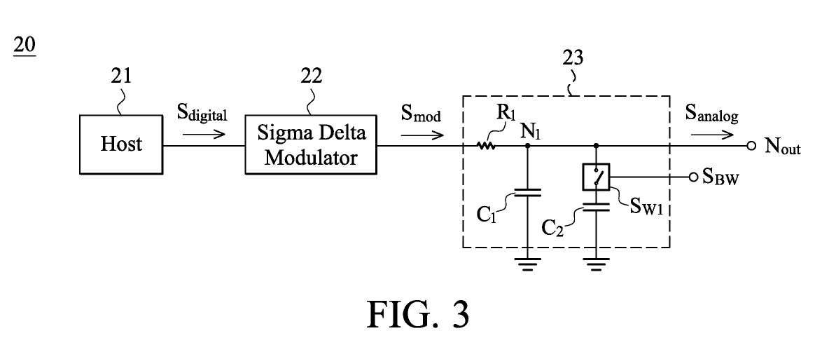

FIG. 3 illustrates a circuit diagram of filtering circuit 23 in the sigma-delta DAC 20 according to one embodiment of the invention. As shown in FIG. 3, the filtering circuit 23 comprises a first resistor R₁, a first capacitor C₁ and a second capacitor C₂. The first resistor R₁ is coupled to the sigma-delta modulator 22. The first capacitor C₁ is coupled to the first resistor R₁, the first switching circuit SW₁, and a reference voltage, wherein a first connection point N₁ of the first capacitor C₁ and the first resistor R₁ is coupled to the output node Nₒᵤₜ. Second capacitor C₂ is coupled to the reference voltage, wherein the first switching circuit SW₁ is coupled between the second capacitor C₂ and the first connection point N₁.

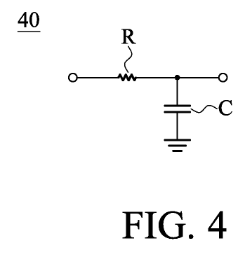

FIG. 4 shows a conventional low pass filter 40. As known in the art, the cut off frequency f_{c} of a conventional low pass filter 40 is given as:

$${f}_{c} = \frac{1}{2 π RC} \qquad Eq . ( 1 )$$

wherein R is the resistance of the resistor and C is the capacitance of the capacitor in a conventional low pass filter 40.

For the filtering circuit 23 shown in FIG. 3, first switching circuit SW₁ adjusts the bandwidth of the filtering circuit 23 by selectively being turned on or off according to the state of the bandwidth switching signal S_{BW}, wherein the bandwidth switching signal S_{BW} can be a signal with a high voltage state and a low voltage state. When first switching circuit SW₁ is turned on (i.e. the two sides of the switching circuit SW1 is thus connected), the first capacitor C₁ is coupled to the second capacitor C₂ in parallel and the total capacitance of the filtering circuit 23 is increased. Alternatively, when first switching circuit SW₁ is turned off, the second capacitor C₂ discontinues and is not coupled to the first connection point N₁ and the total capacitance of the filtering circuit 23 is just the capacitance of the first capacitor C₁. Since there is a trade-off between conversion time/bandwidth of filter and SNR (signal-to-noise ratios) of the output signal S_{analog}, the first switching circuit SW₁ can normally be turned on for increasing the total capacitance of the filtering circuit 23 and obtaining a narrower bandwidth that can achieve better low pass filtering result, and can sometimes be turned off for extending the bandwidth to obtain a faster output signal conversion time. In the embodiment, when there is a sudden change in the digital input signal S_{digital}, for example, when the voltage difference between a previous digital input signal and a current digital input signal is large, the filtering circuit 23 in the sigma-delta DAC 20 can be switched to a high bandwidth mode (for example, the first switching circuit SW₁, as shown in FIG. 3, is turned off) for quickly outputting the current conversion result.

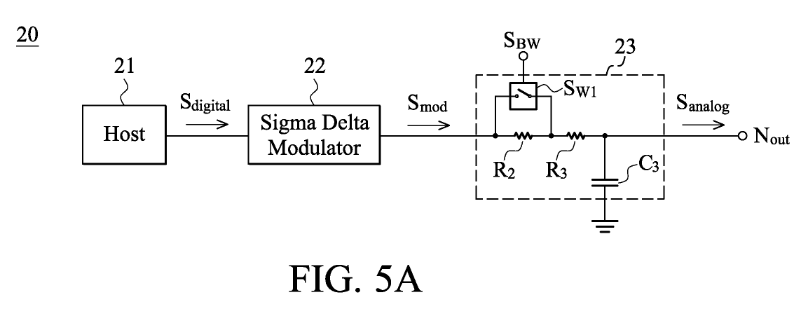

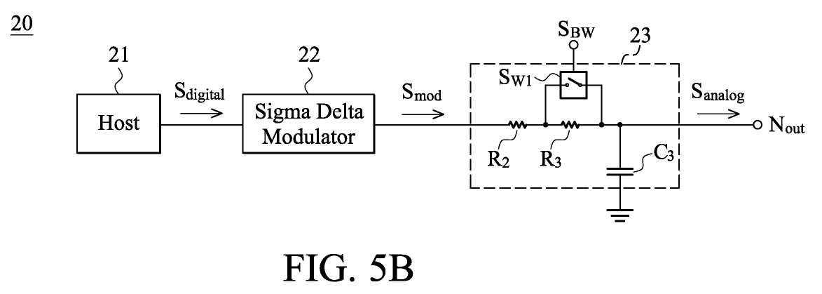

FIG. 5A illustrates another circuit diagram of a filtering circuit 23 in a sigma-delta DAC 20 according to another embodiment of the invention. As shown in FIG. 5, the filtering circuit 23 comprises a second resistor R₂, a third resistor R₃, and a third capacitor C₃. Second resistor R₂ and third resistor R₃ are coupled in serial between the sigma-delta modulator 22 and the output node Nₒᵤₜ, wherein the first switching circuit SW₁ is coupled to the second resistor R₂ in parallel. Third capacitor C₃ is coupled between the output node Nₒᵤₜ and a reference voltage. As discussed above, first switching circuit SW₁ adjusts the bandwidth of the filtering circuit 23 by selectively being turned on or off according to the states of bandwidth switching signal S_{BW}. When first switching circuit SW₁ is turned on, there is a short path generated between the sigma-delta modulator 22 and the third resistor R₃, thus the resistance of the second resistor R₂ is omitted and the total resistance of the filtering circuit 23 is decreased. Alternatively, when first switching circuit SW₁ is turned off, the second resistor R₂ is coupled to the third resistor R₃ in serial and the total resistance of the filtering circuit 23 is increased. Thus, the first switching circuit SW₁ can normally be turned off for increasing the total resistance of the filtering circuit 23 and obtaining a narrower bandwidth that can achieve better low pass filtering result, and can sometimes be turned on for extending the bandwidth to obtain a faster output signal conversion time.

FIG. 5B illustrates another circuit diagram of a filtering circuit 23 in a sigma-delta DAC 20 according to another embodiment of the invention. The embodiment showed in FIG. 5B is a variance of the embodiment showed in FIG. 5A, the switching circuit SW₁ is configured to coupled between two terminals of the third resistor R₃, and the related description is omitted for simplicity.

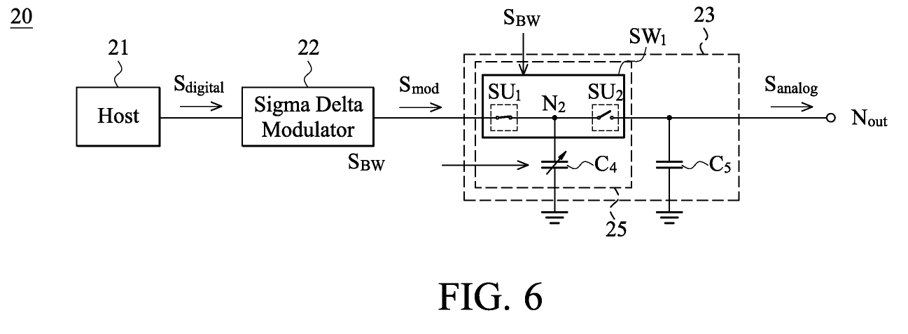

FIG. 6 illustrates another circuit diagram of a filtering circuit 23 in a sigma-delta DAC 20 according to another embodiment of the invention. As shown in FIG. 6, the first switching circuit SW₁ is coupled between the sigma-delta modulator 22 and the output node Nₒᵤₜ. The first switching circuit SW₁ comprises a first switching unit SU₁ coupled to the sigma-delta modulator 22, and a second switching unit SU₂ coupled between the first switching unit SU₁ and the output node Nₒᵤₜ. The filtering circuit 23 shown in FIG. 6 comprises a fourth capacitor C₄ and a fifth capacitor C₅. The fourth capacitor C₄ is coupled between a reference voltage and a second connection point N₂ of the first switching unit SU₁ and the second switching unit SU₂, wherein the fourth capacitor C₄ is an adjustable capacitor. The fifth capacitor C₅ is coupled between the reference voltage and the output node Nₒᵤₜ. In this embodiment, a switch-capacitor 25 is adopted to realize a resistor, wherein the first switch unit SU₁ and the second switch unit SU₂ are alternatively turned on. When the first switch unit SU₁ is turned on, the second switch unit SU₂ is turned off and the fourth capacitor C₄ starts to charge. When the first switch unit SU₁ is turned off, the second switch unit SU₂ is turned on and the charge stored in the fourth capacitor C₄ begins shared usage with the fifth capacitor C₅. The steps are repeated, and the equivalent resistance of the switch-capacitor 25 is determined by the switching frequency f_{sw} of turning on and off the first switch unit SU₁ and the second switch unit SU₂, and the capacitance of the fourth capacitor C₄. As known in the art, the filtering circuit 23 here can be taken as a switch-capacitor low pass filter, and the cut off frequency f_{c} of such the switch-capacitor low pass filter 23 is given as:

$${f}_{c} = \frac{{f}_{sw}}{2 π} \times ln ( \frac{{CAP}_{4} + {CAP}_{5}}{{CAP}_{5}} ) \qquad Eq . ( 2 )$$

, wherein CAP₄ and CAP₅ are the capacitance of the fourth capacitor C₄ and fifth capacitor C₅, respectively.

Thus, by dynamically adjusting the switching frequency f_{sw} and the capacitance CAP₄ of the fourth capacitor C₄, the bandwidth of the switch-capacitor low pass filter 23 can be adjusted. For example, the switching frequency f_{sw} can be increased according to one state of the bandwidth switching signal S_{BW} to obtain the high bandwidth mode of the switch-capacitor low pass filter 23, and in another way, the switching frequency f_{sw} can be decreased according to another state of the bandwidth switching signal S_{BW} to obtain the low bandwidth mode. In addition, since the fourth capacitor C₄ is an adjustable capacitor, the capacitance CAP₄ can also be increased according to one state of the bandwidth switching signal S_{BW} to obtain the high bandwidth mode of the switch-capacitor low pass filter 23, and in another way, the capacitance CAP₄ can be decreased according to another state of the bandwidth switching signal S_{BW} to obtain the low bandwidth mode.

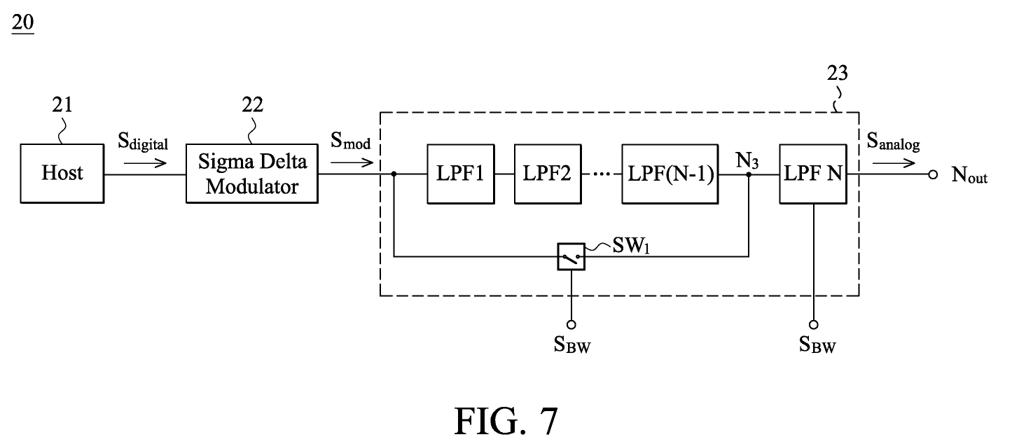

In order to increase the SNR of the converted results, the filtering circuit 23 can be designed with high order. FIG. 7 illustrates another circuit diagram of a filtering circuit 23 in a sigma-delta DAC 20 according to another embodiment of the invention. As shown in FIG. 7, filtering circuit 23 comprises a plurality of low pass filtering units LPF 1, LPF 2˜LPF N coupled in serial between the sigma-delta modulator 22 and the output node Nₒᵤₜ. One terminal of the first switching circuit SW₁ is coupled to a third connection point (such as N₃) between two of the low pass filtering units, and another terminal of the first switching circuit SW₁ is coupled to the sigma-delta modulator 22, the output node N_{out.}, or a fourth connection point between two of other low pass filtering units. In this embodiment, the first switching circuit SW₁ is coupled between the third connection point N₃ and the sigma-delta modulator 22. As discussed above, first switching circuit SW₁ adjusts the bandwidth of the filtering circuit 23 by selectively being turned on or off according to the states of bandwidth switching signal S_{BW}. When first switching circuit SW₁ is turned on, there is a short path generated between the sigma-delta modulator 22 and the input node of LPF N, thus the order of the filtering circuit 23 is decreased for extending the bandwidth of the filtering circuit 23. Alternatively, when first switching circuit SW₁ is turned off, the low pass filter units LPF 1˜LPF N are coupled in serial and the order of the filtering circuit 23 is increased for decreasing the bandwidth of the filtering circuit 23. Thus, the first switching circuit SW₁ can normally be turned off for increasing the order of the filtering circuit 23 and obtaining a narrower bandwidth that can achieve better low pass filtering result, and can sometimes be turned on for extending the bandwidth to obtain a faster output signal conversion time.

In addition, the low pass filter units LPF 1˜LPF N can also be implemented as the filtering circuit 23 embodiments as shown in FIG. 3, FIG. 5 and FIG. 6. For example, the low pass filter unit LPF N that is not influenced by the first switching circuit SW₁ can further comprise a second switching circuit for adjusting the bandwidth of the low pass filtering unit LPF N according to the bandwidth switching signal S_{BW}. Thus, when the first switching circuit SW₁ is turned on for shorting the low pass filter units LPF 1˜LPF (N-1) and obtaining a broader bandwidth, the second switching circuit in LPF N can also be adopted to further adjust the bandwidth of the low pass filtering unit LPF N as discussed above in FIG. 3, FIG. 5 and FIG. 6. Similarly, the bandwidth of the low pass filter units LPF 1˜LPF N can also be adjusted by controlling the switching circuit connected between the resistors or capacitors like the descriptions of FIG. 3, FIG. 5 or FIG. 6.

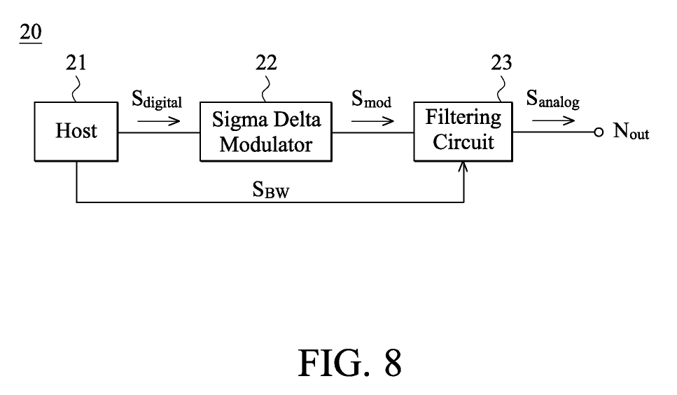

FIG. 8 illustrates a block diagram of the device generating the bandwidth switching signal S_{BW} according to one embodiment of the invention. In the embodiment, the digital input signal S_{digital} can be the commands for controlling certain devices, for example, digital input signal S_{digital} can be a read, write or blank command of an optical disk driver. When there is a sudden change in command for an optical disk driver, such as a command being changed from a previous read command to a write command, it is preferable to output conversion result of the sigma-delta DAC 20 as soon as possible. Thus, the bandwidth of the filtering circuit 23 can be adjusted to a high bandwidth mode so that the sigma-delta DAC 20 can quickly output the current write command, although the current conversion result may suffer from more noise than a low bandwidth mode conversion result and have decreased equivalent bit number of the analog output signal S_{analog}.

For such an application, the host 21 that provides the digital input signal S_{digital} can further provide a high bandwidth indication signal as the bandwidth switching signal S_{BW} to the first switching circuit as shown in FIG. 8, for instructing the first switching circuit to extend the bandwidth of the filtering circuit 23 when the read, write or blank command of the optical disk driver is changed. Since the equivalent bit number of the analog output signal S_{analog} converted by the filtering circuit 23 with higher bandwidth is less than the one with lower bandwidth, the bandwidth switching signal S_{BW} should be changed back again to instruct the first switching circuit to decrease the bandwidth of the filtering circuit 23 after a certain period. Thus, the host 21 further provides a low bandwidth indication signal as the bandwidth switching signal S_{BW} to the first switching circuit described in previous figures for instructing the first switching circuit to decrease the bandwidth of the filtering circuit 23 after providing the high bandwidth indication signal with a preset period.

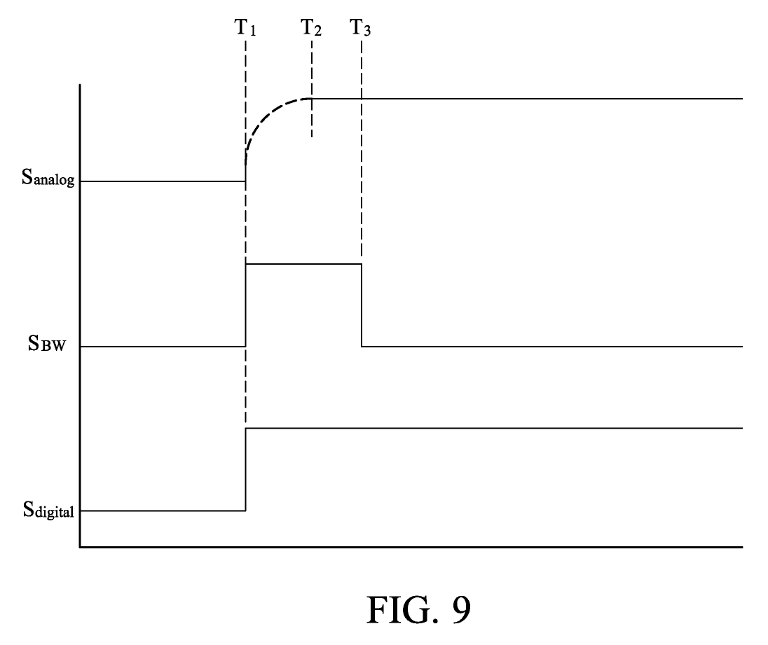

FIG. 9 illustrates the signal waveforms according to the embodiment of the invention. As shown in FIG. 9, in beginning, the filtering circuit is switched to be a low level bandwidth mode for outputting the conversion with better SNR. When there is a large change in digital input signal S_{digital} at time T₁, the bandwidth switching signal S_{BW} is changed, for example, from logic low to high to instruct the first switching circuit to extend the bandwidth of the filtering circuit. Thus, the analog output signal S_{analog} can be quickly changed to another value at time T₂ accordingly. And after the analog output signal S_{analog} reaches the desired value, the bandwidth switching signal S_{BW} is changed back to low at time T₃ to instruct the first switching circuit to decrease the bandwidth of the filtering circuit. Thus, the equivalent bit number (or SNR) of the analog output signal S_{analog} is increased.

According to another embodiment of the invention, host 21 can also directly output the digital input signal S_{digital} as the bandwidth switching signal S_{BW} for instructing the first switching circuit to extend the bandwidth of the filtering circuit 23, and output a reset signal to the first switching circuit of the filtering circuit 23 to decrease the bandwidth after a preset period. According to yet another embodiment of the invention, host 21 can also observe the variation of the analog output signals S_{analog}. When host 21 detects that the voltage difference between a current analog output signal S_{analog} and a current target output voltage exceeds a threshold, it means that sigma-delta DAC 20 has taken too long time to convert the analog output signal S_{analog} to the target voltage. Thus, the host 21 provides a high bandwidth indication signal as the bandwidth switching signal S_{BW} to the first switching circuit of the filtering circuit 23 to instruct the first switching circuit to extend the bandwidth, and further provide a low bandwidth indication signal as the bandwidth switching signal S_{BW} to the first switching circuit of the filtering circuit 23 for instructing the first switching circuit to decrease the bandwidth after providing the high bandwidth indication signal with a preset period.

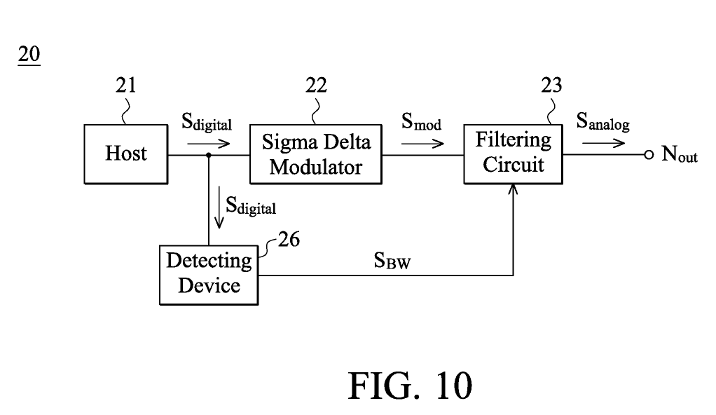

FIG. 10 illustrates another block diagram of the device generating the bandwidth switching signal S_{BW} according to one embodiment of the invention. In the embodiment, sigma-delta DAC 20 further comprises a detecting device 26 coupled to the host to detect a voltage level variation of the digital input signal S_{digital}, and output a high bandwidth control signal as the bandwidth switching signal S_{BW} to the first switching circuit of the filtering circuit 23 to instruct the first switching circuit to extend the bandwidth when the voltage variation exceeds a threshold. After outputting the high bandwidth control signal with a preset period, the detecting device 26 further outputs a low bandwidth control signal as the bandwidth switching signal S_{BW} to the first switching circuit of the filtering circuit 23 to instruct the first switching circuit to decrease the bandwidth. Therefore, the bandwidth can be adjusted automatically in such kind of embodiments.

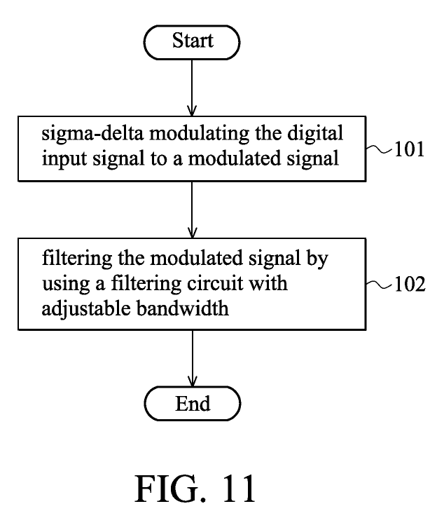

FIG. 11 illustrates the flow chart of a digital to analog converting method according to the embodiment of the invention. Firstly, digital input signal received from a host is sigma-delta modulated to a modulated signal by using a sigma-delta modulator (step 101). Next, the modulated signal is filtered by using a filtering circuit with adjustable bandwidth to generate an analog output signal from an output node, wherein the filtering circuit comprises a first switching circuit for adjusting the bandwidth of the filtering circuit according to a bandwidth switching signal (102).

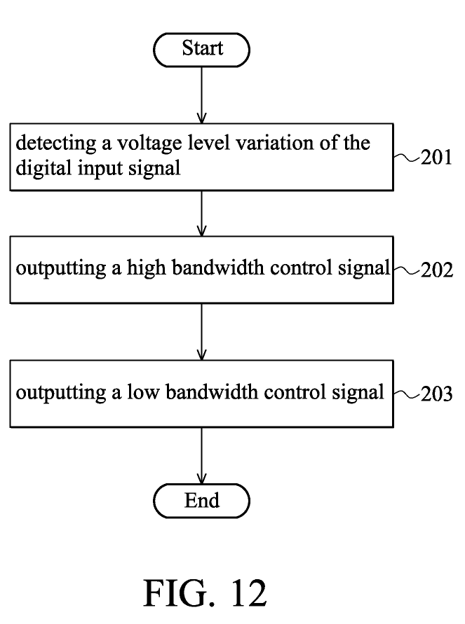

FIG. 12 illustrates the flow chart of generating a bandwidth switching signal according to one embodiment of the invention. Firstly, a voltage level variation of the digital input signal is detected (step 201). Next, a high bandwidth control signal is outputted as the bandwidth switching signal for instructing the first switching circuit to extend the bandwidth of the filtering circuit when the voltage variation exceeds a threshold (step 202). Finally, a low bandwidth control signal is outputted as the bandwidth switching signal for instructing the first switching circuit to decrease the bandwidth of the filtering circuit after outputting the high bandwidth control signal with a preset period (step 203). According to one embodiment of the invention, the digital input signal can be the commands for controlling certain devices, for example, digital input signal can be a read, write or blank command of an optical disk driver.

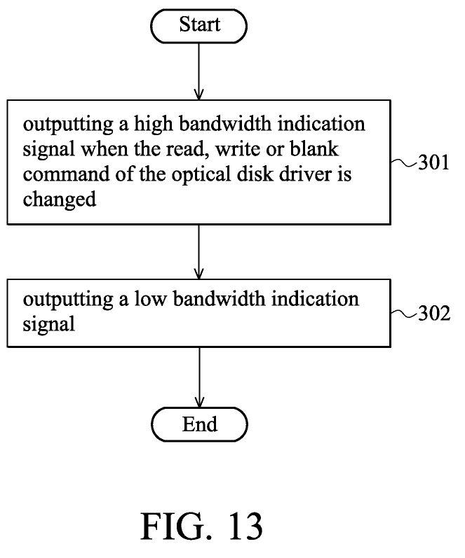

FIG. 13 illustrates the flow chart of generating a bandwidth switching signal when digital input signal is a read, write or blank command of an optical disk driver. Firstly, a high bandwidth indication signal is outputted as the bandwidth switching signal for instructing the first switching circuit to extend the bandwidth of the filtering circuit when the read, write or blank command of the optical disk driver is changed (step 301). Next, a low bandwidth indication signal is outputted as the bandwidth switching signal for instructing the first switching circuit to decrease the bandwidth of the filtering circuit after providing the high bandwidth indication signal with a preset period (step 302).

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A digital to analog converter (DAC) for converting a digital input signal provided by a host to an analog output signal, comprising:
a modulator receiving the digital input signal, modulating the digital input signal, and outputting a modulated signal; and
a filtering circuit receiving the modulated signal, low pass filtering the modulated signal, and outputting the analog output signal to an output node, wherein the filtering circuit comprises a first switching circuit for adjusting the bandwidth of the filtering circuit according to a bandwidth switching signal.

2. The digital to analog converter as claimed in claim 1, wherein the filtering circuit further comprises:
a first resistor coupled to the modulator;
a first capacitor coupled to the first resistor, the first switching circuit, and a reference voltage, wherein a first connection point of the first capacitor and the first resistor is coupled to the output node; and
a second capacitor coupled to the reference voltage, wherein the first switching circuit is coupled between the second capacitor and the first connection point.

3. The digital to analog converter as claimed in claim 1, wherein the filtering circuit further comprises:
a second resistor and a third resistor coupled in serial between the modulator and the output node, wherein the first switching circuit is coupled to the second resistor in parallel; and
a third capacitor coupled between the output node and a reference voltage.

4. The digital to analog converter as claimed in claim 1, wherein the first switching circuit is coupled between the modulator and the output node, the first switching circuit comprises a first switching unit coupled to the modulator and a second switching unit coupled between the first switching unit, and the output node, and the filtering circuit further comprises:
a fourth capacitor coupled between a reference voltage and a second connection point of the first switching unit and the second switching unit, wherein the fourth capacitor is an adjustable capacitor; and
a fifth capacitor coupled between the reference voltage and the output node.

5. The digital to analog converter as claimed in claim 1, further comprising a detecting device coupled to the host for detecting a voltage level variation of the digital input signal, and outputting a high bandwidth control signal as the bandwidth switching signal to the first switching circuit for instructing the first switching circuit to extend the bandwidth of the filtering circuit when the voltage variation exceeds a threshold.

6. The digital to analog converter as claimed in claim 5, wherein the detecting device further outputs a low bandwidth control signal as the bandwidth switching signal to the first switching circuit for instructing the first switching circuit to decrease the bandwidth of the filtering circuit after outputting the high bandwidth control signal with a preset period.

7. The digital to analog converter as claimed in claim 1, wherein the digital input signal is a read, write or blank command of an optical disk driver.

8. The digital to analog converter as claimed in claim 7, wherein the host provides a high bandwidth indication signal as the bandwidth switching signal to the first switching circuit for instructing the first switching circuit to extend the bandwidth of the filtering circuit when the read, write or blank command of the optical disk driver is changed.

9. The digital to analog converter as claimed in claim 8, wherein the host further provides a low bandwidth indication signal as the bandwidth switching signal to the first switching circuit for instructing the first switching circuit to decrease the bandwidth of the filtering circuit after providing the high bandwidth indication signal with a preset period.

10. The digital to analog converter as claimed in claim 1, wherein the filtering circuit further comprises a plurality of low pass filtering units coupled in serial between the modulator and the output node, wherein one terminal of the first switching circuit is coupled to a third connection point between two of the low pass filtering units, and another terminal of the first switching circuit is coupled to the modulator, the output node, or a fourth connection point between two of other low pass filtering units.

11. The digital to analog converter as claimed in claim 10, wherein one of the low pass filtering units comprises a second switching circuit for adjusting the bandwidth of the low pass filtering unit according to the bandwidth switching signal.

12. The digital to analog converter as claimed in claim 11, wherein the low pass filter unit further comprises:
a fourth resistor coupled to an input node of the low pass filter unit;
a sixth capacitor coupled to the fourth resistor, the second switching circuit, and a reference voltage, wherein a fifth connection point of the sixth capacitor and the fourth resistor is coupled to an output node of the low pass filter unit; and
a seventh capacitor coupled to the reference voltage, wherein the second switching circuit is coupled between the seventh capacitor and the fifth connection point.

13. The digital to analog converter as claimed in claim 11, wherein the low pass filter unit further comprises:
a fifth resistor and a sixth resistor coupled in serial between an input node and an output node of the low pass filter unit, wherein the second switching circuit is coupled to fifth second resistor in parallel; and
an eighth capacitor coupled between the output node of the low pass filter unit and a reference voltage.

14. The digital to analog converter as claimed in claim 11, wherein the second switching circuit is coupled between an input node and an output node of the low pass filter unit, the second switching circuit comprises a third switching unit coupled to the input node of the low pass filter unit and a fourth switching unit coupled between the third switching unit, and the output node of the low pass filter unit, and the low pass filter unit further comprises:
a ninth capacitor coupled between a reference voltage and a sixth connection point of the third switching unit and the fourth switching unit, wherein the ninth capacitor is an adjustable capacitor; and
a tenth capacitor coupled between the reference voltage and the output node of the low pass filter.

15. A digital to analog converting method for converting a digital input signal received from a host to an analog signal, the digital to analog converting method comprising:
modulating the digital input signal to a modulated signal; and
filtering the modulated signal and adjusting bandwidth by a filtering circuit, to generate an analog output signal according to a bandwidth switching signal.

16. The digital to analog converting method as claimed in claim 15, further comprising:
detecting a voltage level variation of the digital input signal;
outputting a high bandwidth control signal as the bandwidth switching signal for extending the bandwidth of the filtering circuit when the voltage variation exceeds a threshold; and
outputting a low bandwidth control signal as the bandwidth switching signal for decreasing the bandwidth of the filtering circuit after outputting the high bandwidth control signal with a preset period.

17. The digital to analog converting method as claimed in claim 15, wherein the digital input signal is a read, write or blank command of an optical disk driver.

18. The digital to analog converting method as claimed in claim 17, further comprising:
outputting a high bandwidth indication signal as the bandwidth switching signal for extending the bandwidth of the filtering circuit when the read, write or blank command of the optical disk driver is changed; and
outputting a low bandwidth indication signal as the bandwidth switching signal for decreasing the bandwidth of the filtering circuit after providing the high bandwidth indication signal with a preset period.
